(19) United States
(12) Patent Application Publication
(10) Pub. No.: US 2025/0386610 A1
(43) Pub. Date: Dec. 18, 2025

(54) OPTICAL IMAGE SENSOR MODULE ARRAY, OPTICAL IMAGE SENSOR MODULE, AND MANUFACTURING METHOD THEREOF

(71) Applicant: Medimaging Integrated Solution, Inc., Hsinchu (TW)

(72) Inventors: Yi-Han HUANG, Hsinchu (TW); Shangyi WU, Hsinchu (TW); Chu-Ming CHENG, Hsinchu (TW)

(21) Appl. No.: 19/174,984

(22) Filed: Apr. 10, 2025

(30) Foreign Application Priority Data
Jun. 12, 2024 (TW) 113121738

(51) Int. Cl. H10F 39/00

(52) U.S. Cl. CPC H10F 39/8063; H10F 39/024; H10F 39/8057

(57) ABSTRACT

The present invention provides an optical image sensor module array, an optical image sensor module, and a manufacturing method thereof. The method involves providing a lens module array formed by stacking multiple lens layers; filling an adhesive material between the lens layers for bonding; making glue runners by performing the first cut based on alignment marks; filling a light-shielding material to cover the lens units; attaching one side of an image sensor onto one surface of each lens unit to form the optical image sensor module array; and cutting the light-shielding material along the glue runners to separate the lens units and form a plurality of optical image sensor modules for endoscope lens assemblies. Therefore, the present invention enables efficient mass production of high-quality optical image sensor modules of endoscope lens assemblies and allows flexible configuration of image sensors to achieve optimal imaging performance.

### BACKGROUND OF THE INVENTION

### 1. Field of the Invention

The present invention relates to a field of endoscopic lens assemblies, particularly to an optical image sensor module array, an optical image sensor module, and a manufacturing method thereof.

### 2. Description of the Prior Art

The current optical image sensor modules used in endoscopes are developing toward miniaturization. In general, the image capturing lens module having been assembled to the barrel, which is called the barrel-type lens module thereinafter, is aligned and assembled to the image sensor that has been bonded to the carrier board (PCB or FPC) through an automatic alignment device. A platform is matched with the image sensor through a multiaxial adjustment machine, and an image calibration is performed to obtain the optimized test image. Then, an adhesive is dispensed to fix the relative position of the image capturing lens module and the image sensor and obtain a complete image sensor module having an image capturing lens module. However, the abovementioned technology is used to fabricate a single image sensor module. In the abovementioned technology, the assembled barrel-type lens module is further assembled to the image sensor. Thus, the output image sensor module has a larger outer diameter. After the LED light source is added, the final size of the front end of the endoscope will be too large to meet the tendency of miniaturization.

Another technology of fabricating optical image sensor modules adopts a wafer-level based technology: the completed wafer-level package sensors and the corresponding wafer-level lenses are aligned and stacked together adhesively layer by layer. The finished array is cut to obtain the required image sensor modules. Then, a black or dark-color material is coated on the perimeter of the image sensor module to shield light lest stray light enter the lens and affect the image quality. However, the wafer-level package process is unlikely to automatically align the lenses and the image sensors. Each wafer-level lens can only be aligned and adhesively assembled through alignment points. In other words, the wafer-level package process cannot adjust the position according to image quality and is unlikely to control the imaging quality of each image sensor on the wafer. Thus, the yield thereof is degraded. Besides, the wafer-level package process is unlikely screen out the damaged image sensors during fabrication. Though some damaged image sensors have been known, the lens package process cannot be interrupted but must be completed thoroughly. Then is increased the cost and degraded the yield. Besides, the optics specifications (such as the field of view and the depth of field) of the abovementioned technology are unlikely to adjust any more once the specifications have been decided. Therefore, they cannot be adjusted to satisfy requirements of different endoscopes by the users. If the specifications are intended to be changed, much money would be spent in redesigning the forming molds of the wafer-level lenses. Hence, the wafer-level lens is more expensive than the barrel-type lens in such a situation. Therefore, the wafer-level lens is harder to fabricate, lower in yield, and higher in cost.

Accordingly, the present invention proposes an optical image sensor module array, an optical image sensor module, and a manufacturing method thereof to overcome the problems of the conventional technologies.

Accordingly, the market eagerly looks forward to a handheld non-contact tonometer, which is compacter, more lightweight, and easy-to-operate, whereby the people self-caring themselves can use it conveniently at home.

### SUMMARY OF THE INVENTION

One objective of the present invention is to provide an optical image sensor module array, an optical image sensor module, and a manufacturing method thereof to solve the conventional problems of endoscopes, including too large a lens assembly, complicated fabrication processes, high cost, and inflexibility of adjusting optics specifications.

In order to achieve the abovementioned objective, the present invention provides a manufacturing method of an optical image sensor module, which comprises steps:
providing a lens module array, wherein the lens module array is formed by stacking a plurality of lens layers; the plurality of lens layers respectively has a surface and a plurality of alignment marks; the plurality of alignment marks is disposed on the surface; the plurality of lens layers and the plurality of alignment marks define a plurality of lens units arranged in an array;
filling an adhesive material into the gaps between the plurality of lens layers to fix the plurality of lens layers adhesively and form the plurality of lens units;
cutting the lens module array along the plurality of alignment marks to form a plurality of glue runners;
filling a light-shielding material into the plurality of glue runners and curing the light-shielding material to make the light-shielding material wrap the perimeters of the plurality of lens units, wherein the light-shielding material is prevented from covering the surface of the plurality of lens units;
attaching one side of an image sensor onto one surface of each lens unit before filling the light-shielding material into the plurality of glue runners and curing the light-shielding material or after filling the light-shielding material into the plurality of glue runners and curing the light-shielding material or before the adhesive material is filled into the gaps between the plurality of lens layers, wherein another side of the image sensor protrudes outward with respect to the lens unit and neighbors the surface of the lens module array to form an optical image sensor module array; and
cutting the light-shielding material along the sidewalls of the plurality of glue runners to separate the plurality of lens units and form optical-blocking layers around the perimeters of the plurality of lens units to generate a plurality of optical image sensor modules.

In order to achieve the abovementioned objective, the present invention also provides an optical image sensor module array, which comprises a lens module array, an optical-blocking layer, and a plurality of image sensors. The lens module array includes a plurality of lens layers and a plurality of alignment marks. The plurality of lens layers is stacked up. A adhesive material is disposed between the plurality of lens layers. The plurality of alignment marks is arranged on the surfaces of the plurality of lens layers. The plurality of lens layers and the plurality of alignment marks define a plurality of lens units arranged in array. A plurality of glue runners is formed in the plurality of lens layers along the plurality of alignment marks. The optical-blocking layer is disposed inside the plurality of glue runners, wrapping the outer sidewalls of the lens units and prevented from covering the surfaces of the lens units. One side of each of the plurality of image sensors is attached onto one surface of each of the plurality of lens units. Another side of each of the plurality of image sensors protrudes outward with respect to the lens unit and neighbors the surface of the lens module array.

In order to achieve the abovementioned objective, the present invention also provides an optical image sensor module, which is one of the optical image sensor modules manufactured by the abovementioned manufacturing method of an optical image sensor module.

According to the above description, the lens module array of the present invention is formed via stacking a plurality of lens layers; the optical-blocking layer wraps the outer sidewalls of the lens units; the image sensor is arranged on one surface of the lens unit. The technology disclosed by the present invention can fabricate an optical-blocking layer-carrying optical image sensor module array and an optical-blocking layer-carrying optical image sensor module to provide more optical functions and better image quality. Further, the present invention can facilitate mass production, lower cost, raise yield, retard stray light, and promote image quality.

The objective, technologies, features and advantages of the present invention will become apparent from the following description in conjunction with the accompanying drawings wherein certain embodiments of the present invention are set forth by way of illustration and example.

### BRIEF DESCRIPTION OF THE DRAWINGS

The foregoing conceptions and their accompanying advantages of this invention will become more readily appreciated after being better understood by referring to the following detailed description, in conjunction with the accompanying drawings, wherein:

FIG. 1 is a flowchart of a first embodiment of a manufacturing method of an optical image sensor module according to the present invention;

FIG. 2A is a first diagram schematically showing Step S11 of FIG. 1;

FIG. 2B is a second diagram schematically showing Step S11 of FIG. 1;

FIG. 2C is a cross-sectional view taken along Line A-A′ in FIG. 2B;

FIG. 2D, FIG. 2E, FIG. 2F and FIG. 2G are diagrams schematically showing Step S12 of FIG. 1;

FIG. 2H is a diagram schematically showing Step S13 of FIG. 1;

FIG. 21 is a diagram schematically showing Step S14 of FIG. 1;

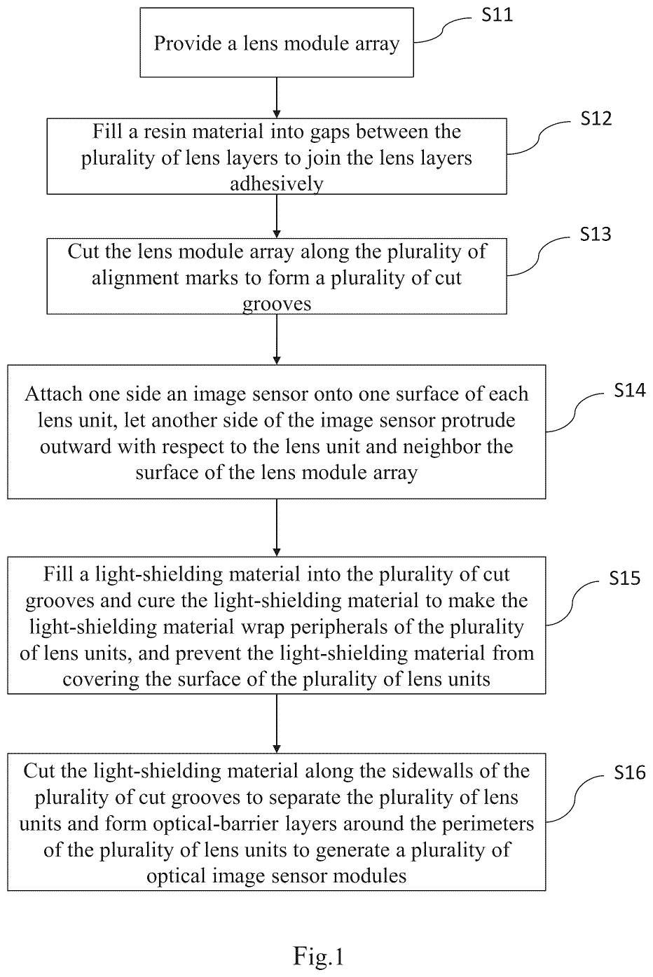

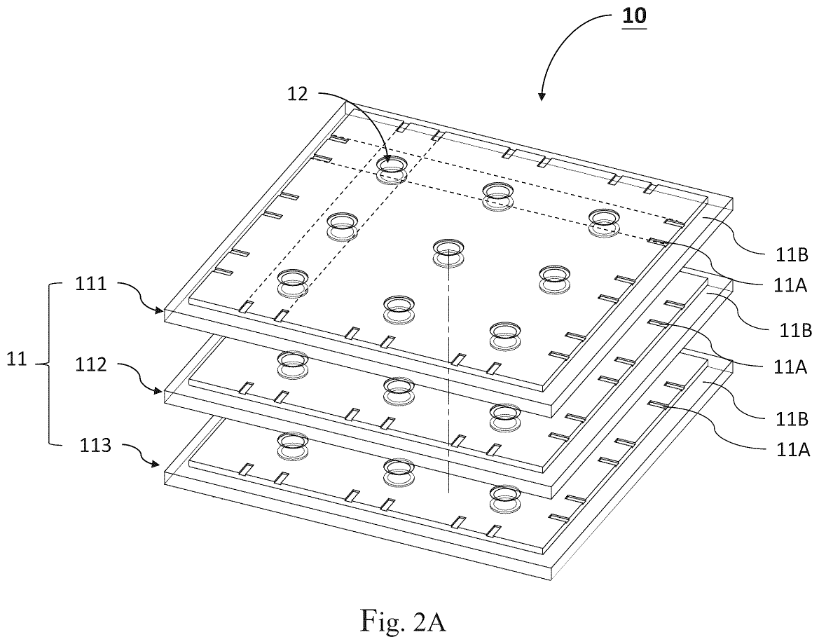

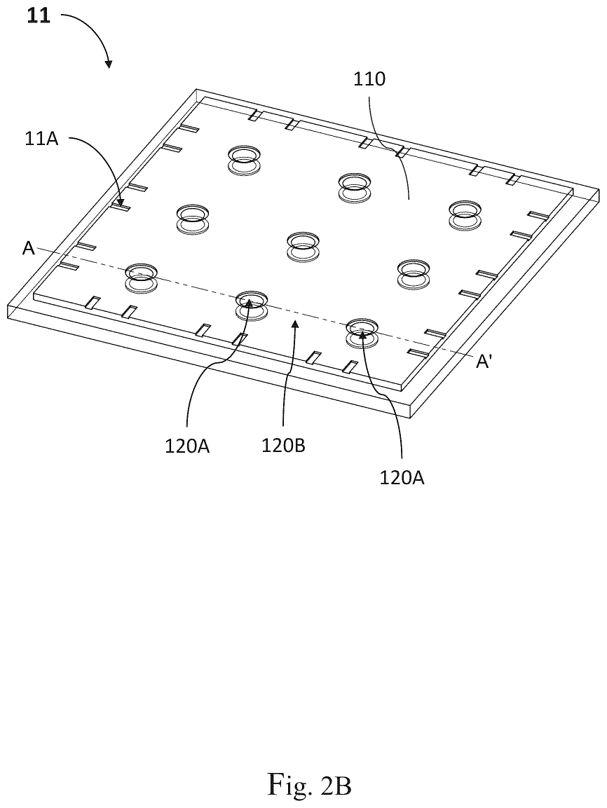

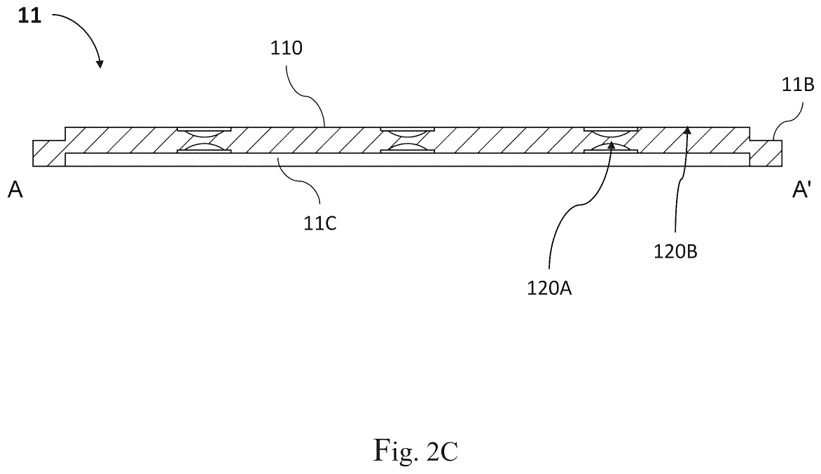

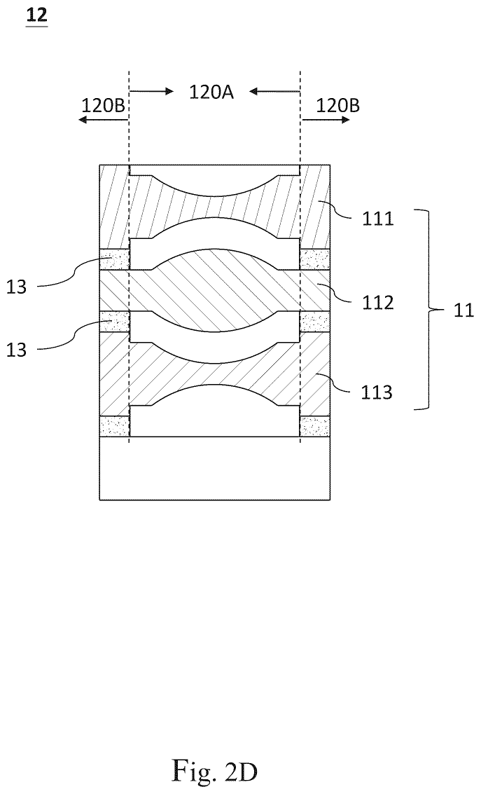

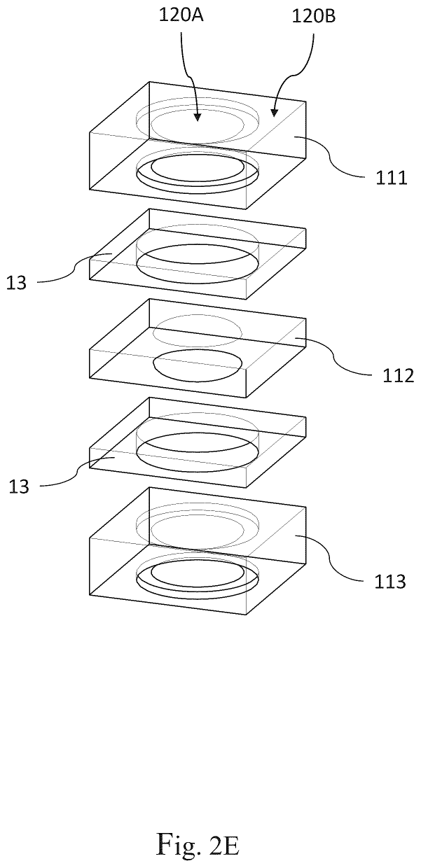

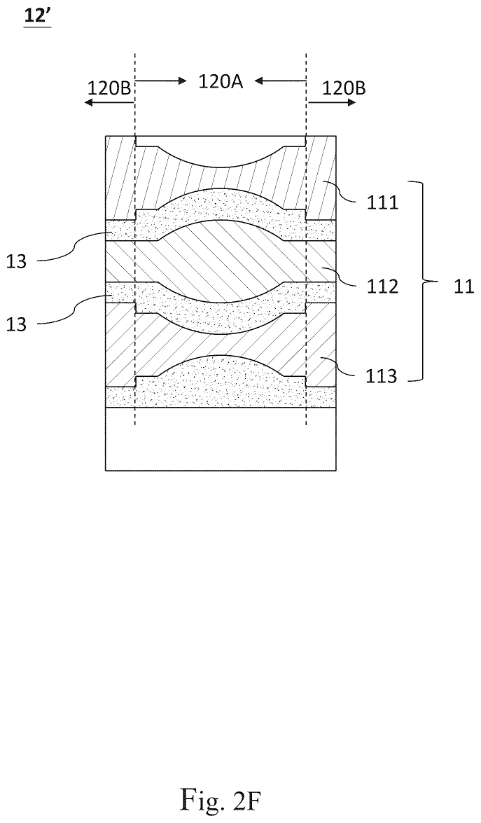

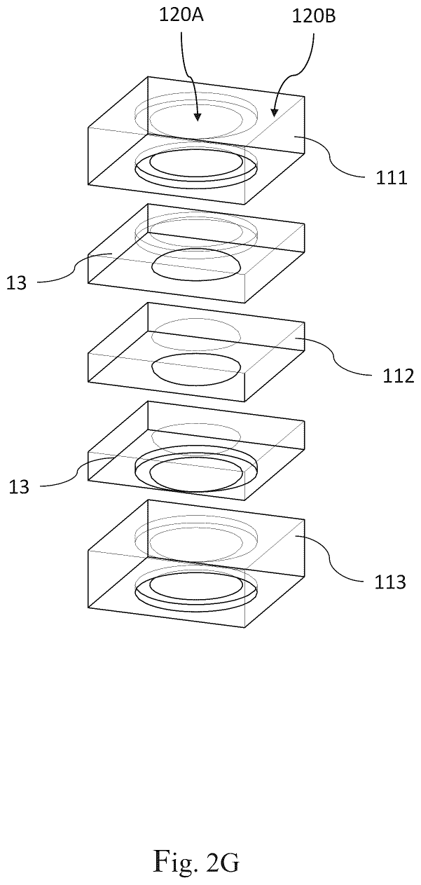

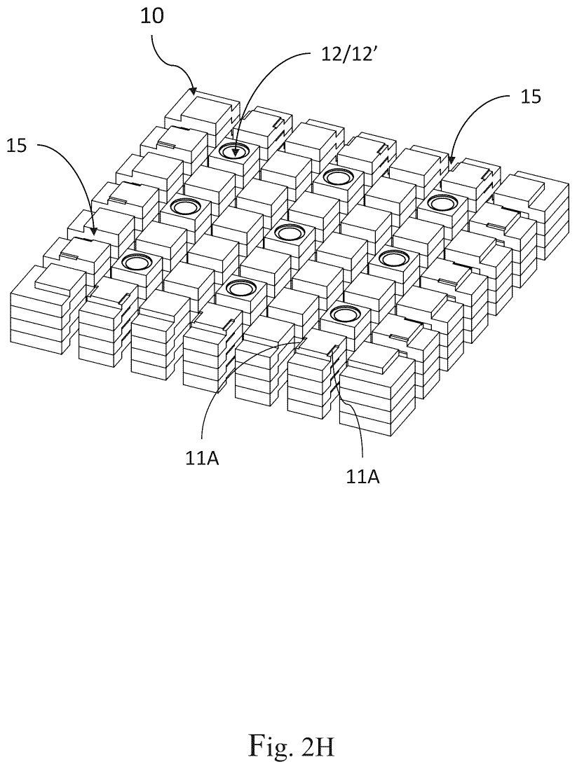

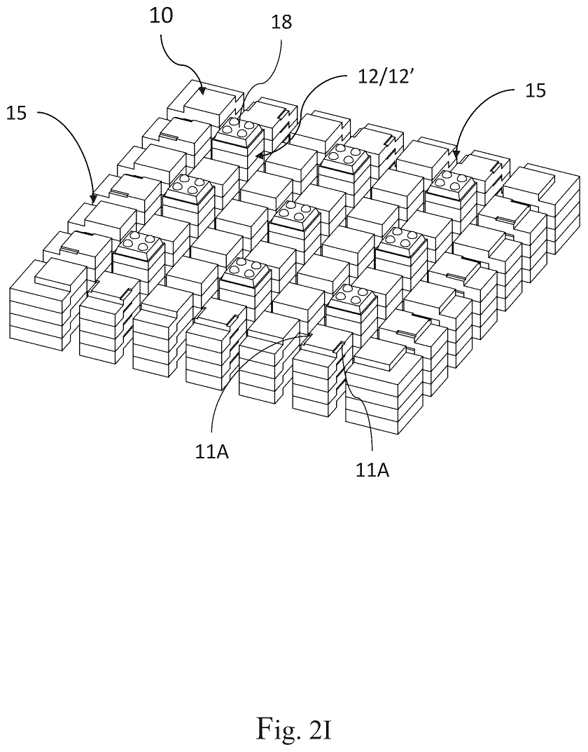

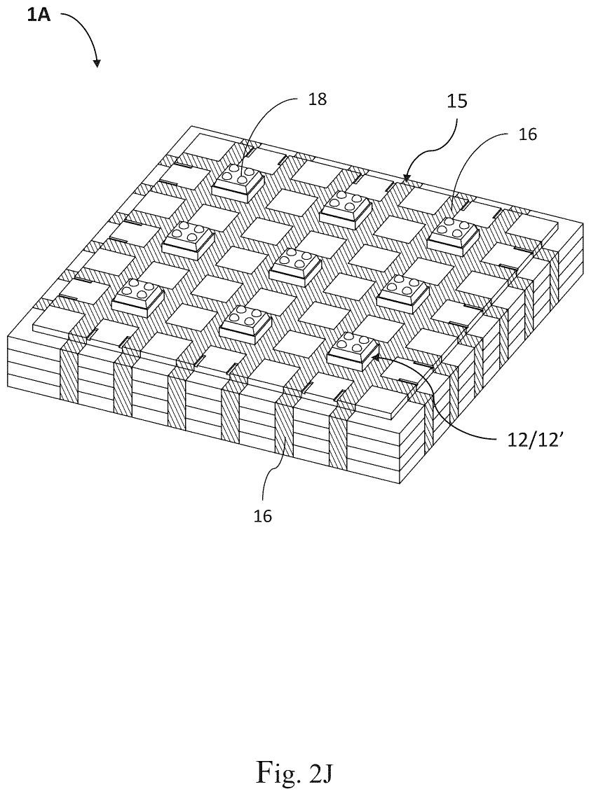

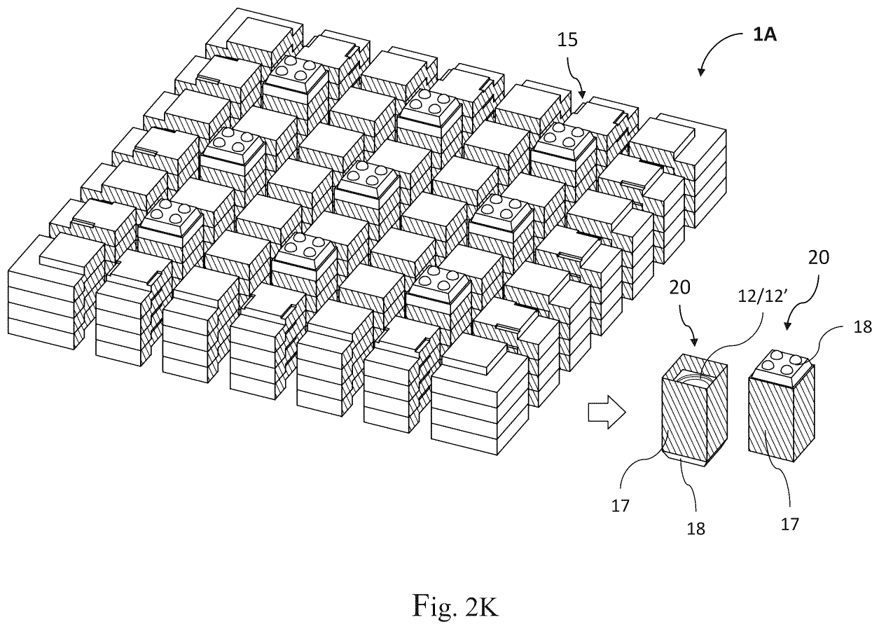

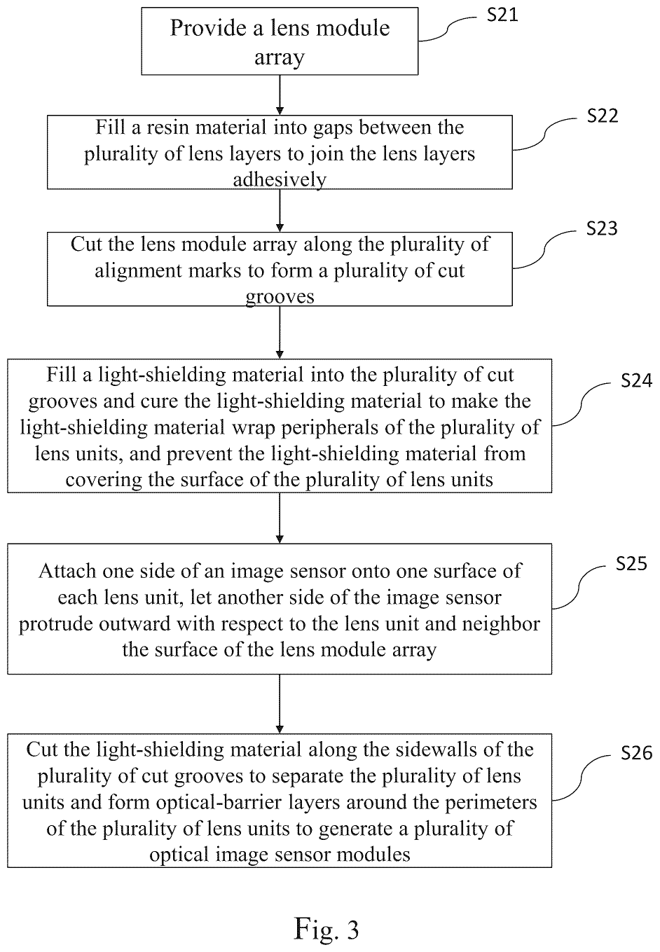

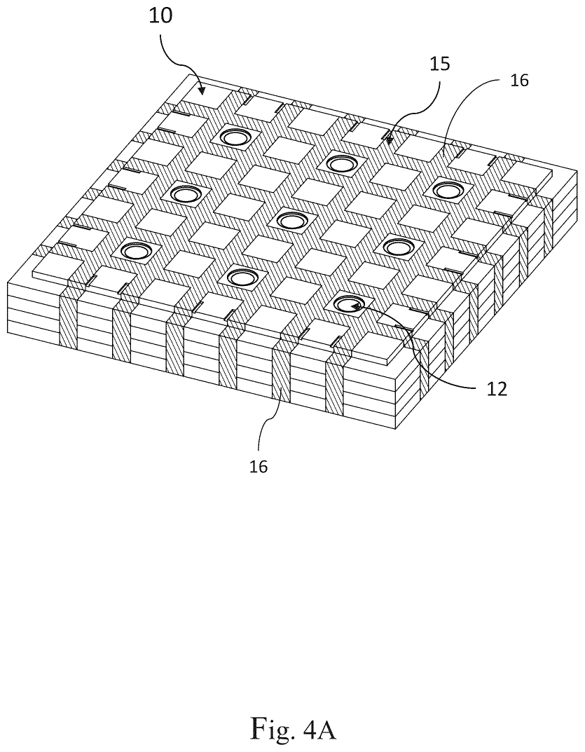

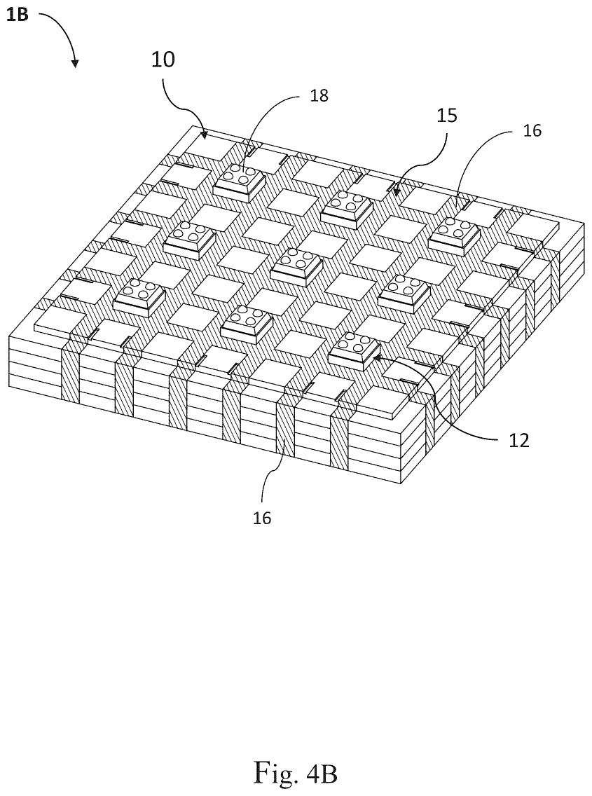

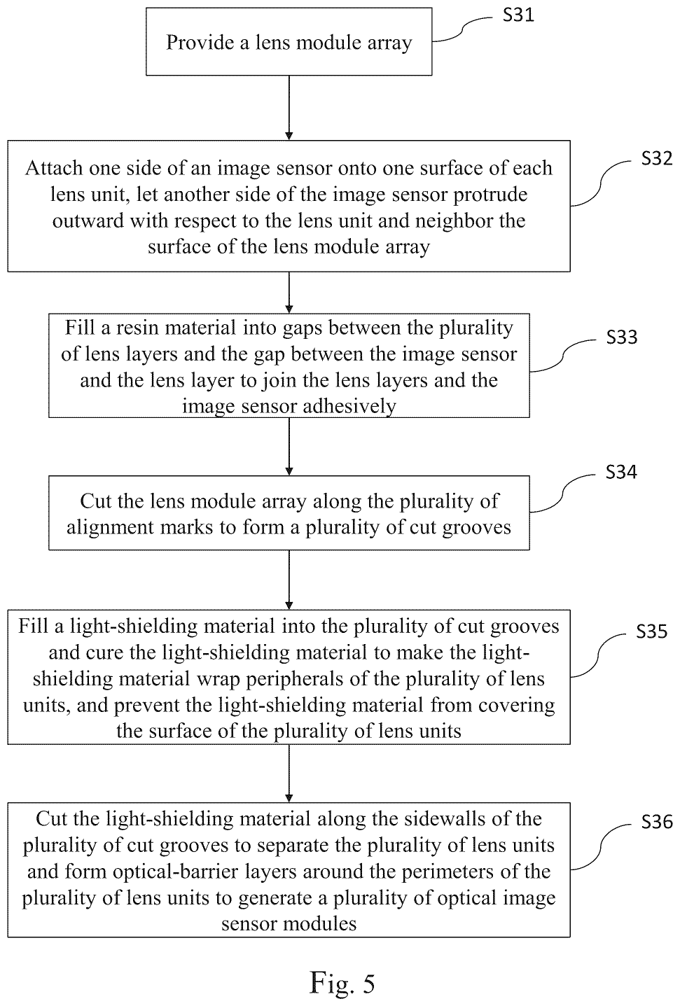

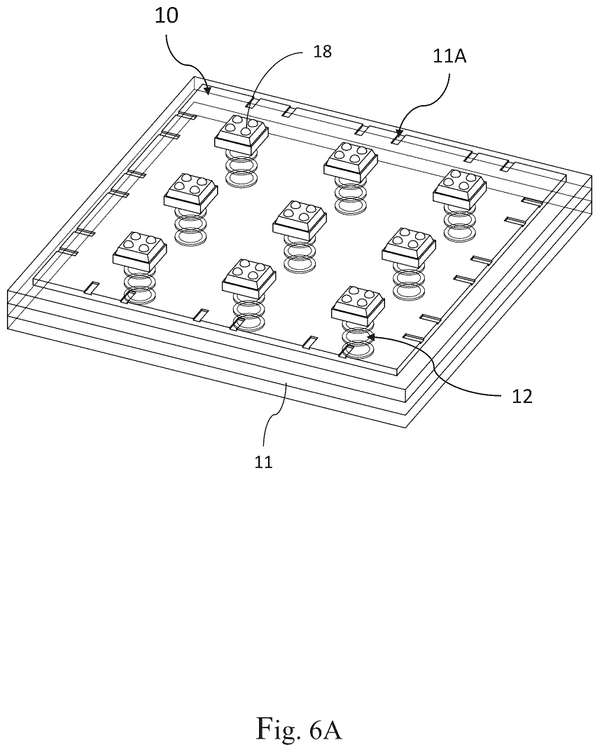

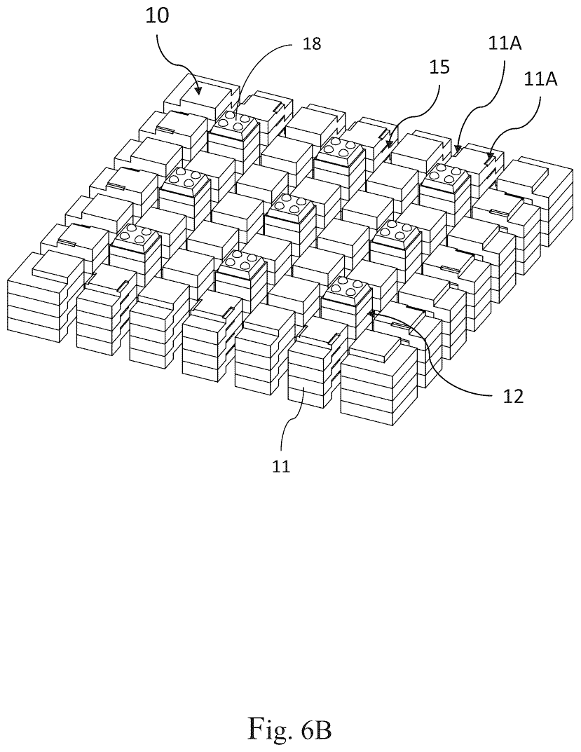

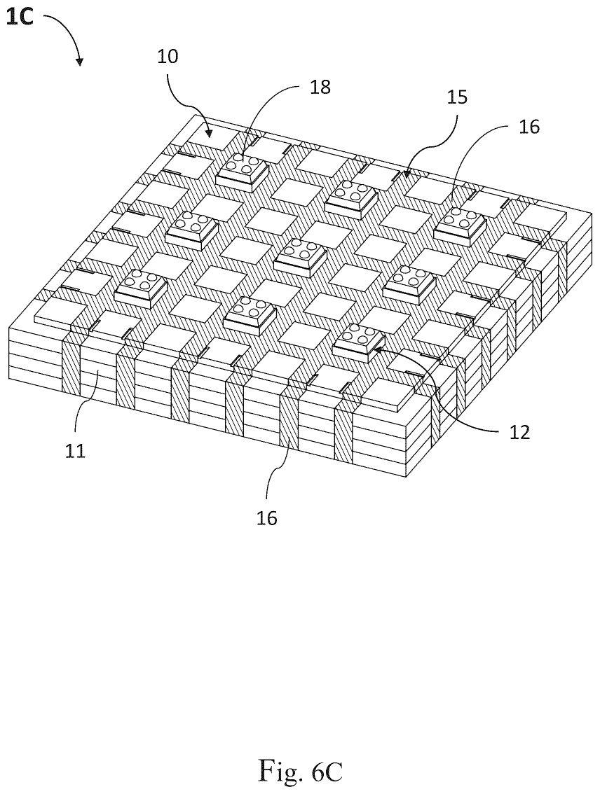

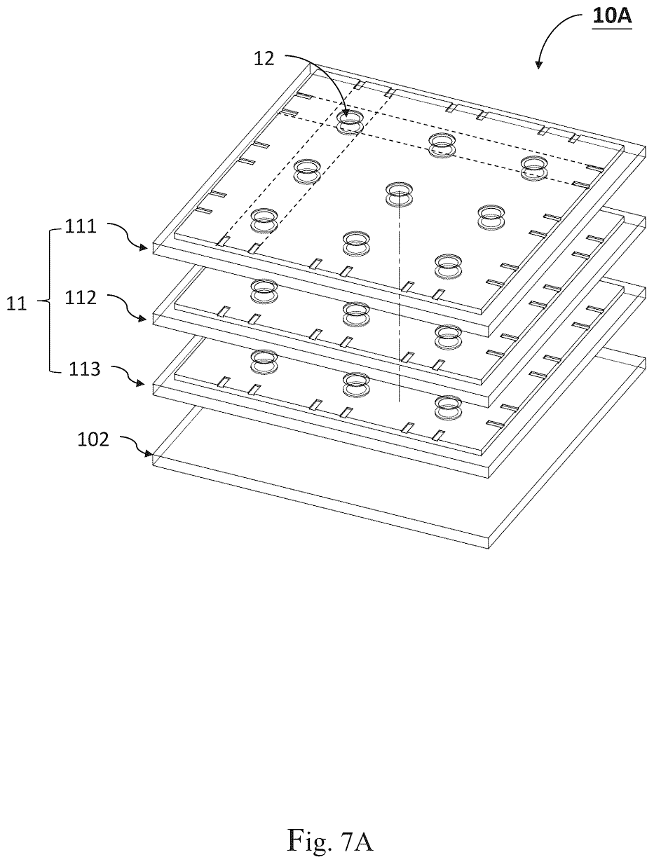

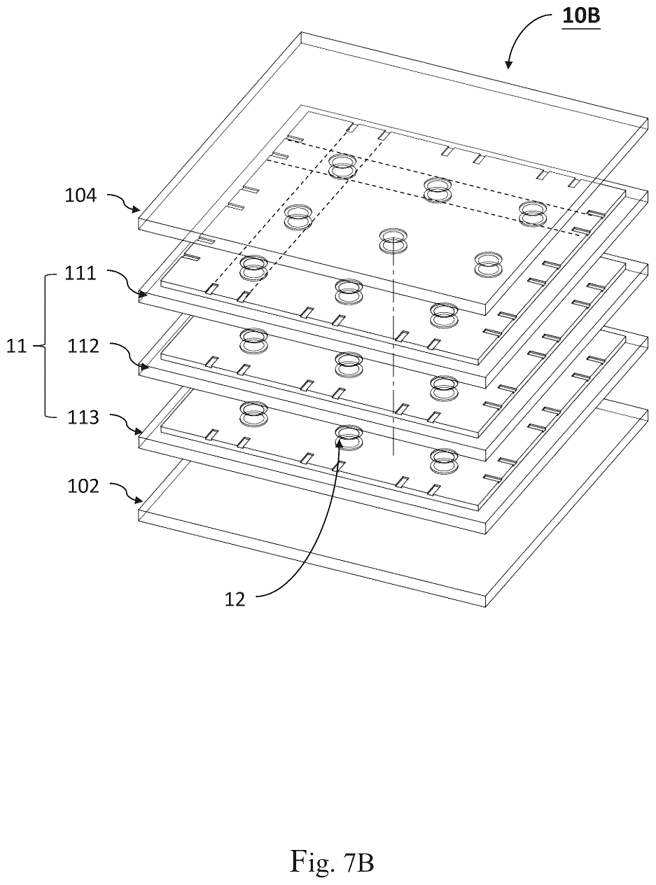

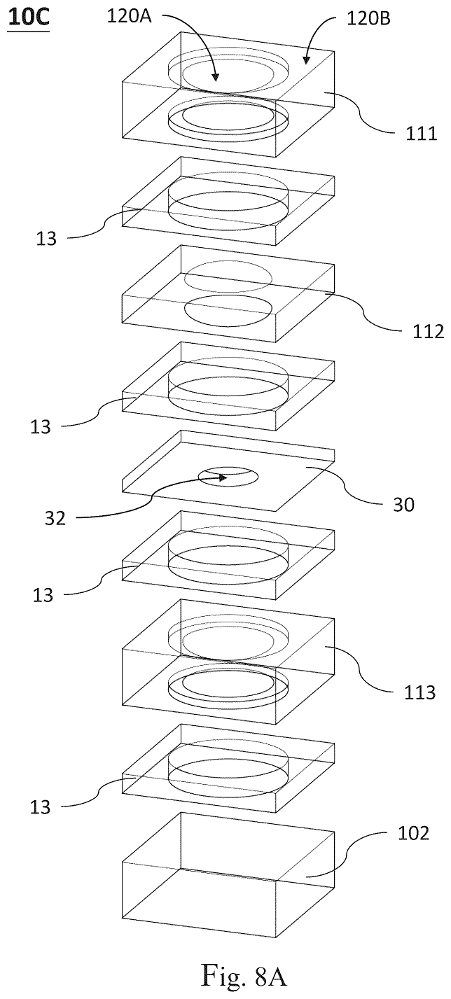

FIG. 2J is a diagram schematically showing Step S15 of FIG. 1;

FIG. 2K is a diagram schematically showing Step S16 of FIG. 1;

FIG. 3 is a flowchart of a second embodiment of a manufacturing method of an optical image sensor module according to the present invention;

FIG. 4A is a diagram schematically showing Step S24 of FIG. 3;

FIG. 4B is a diagram schematically showing Step S25 of FIG. 3;

FIG. 5 is a flowchart of a third embodiment of a manufacturing method of an optical image sensor module according to the present invention;

FIG. 6A is a diagram schematically showing Step S32 of FIG. 5;

FIG. 6B is a diagram schematically showing Step S34 of FIG. 5;

FIG. 6C is a diagram schematically showing Step S35 of FIG. 5;

FIG. 7A, FIG. 7B, FIG. 8A and FIG. 8B are diagrams respectively showing lens module arrays according to embodiments of the present invention;

FIG. 9 is a diagram schematically showing an optical image sensor module array according to one embodiment of the present invention;

FIG. 10A and FIG. 10B are diagrams schematically showing an optical image sensor module according to one embodiment of the present invention.

### DESCRIPTION OF THE PREFERRED EMBODIMENTS

Various embodiments of the present invention will be described in detail below and illustrated in conjunction with the accompanying drawings. In addition to these detailed descriptions, the present invention can be widely implemented in other embodiments, and apparent alternations, modifications and equivalent changes of any mentioned embodiments are all included within the scope of the present invention and based on the scope of the Claims. In the descriptions of the specification, in order to make readers have a more complete understanding about the present invention, many specific details are provided; however, the present invention may be implemented without parts of or all the specific details. In addition, the well-known steps or elements are not described in detail, in order to avoid unnecessary limitations to the present invention. Same or similar elements in Figures will be indicated by same or similar reference numbers. It is noted that the Figures are schematic and may not represent the actual size or number of the elements. For clearness of the Figures, some details may not be fully depicted.

The embodiments of the present invention will be further demonstrated in details hereinafter in cooperation with the corresponding drawings. In the drawings and the specification, the same numerals represent the same or the like elements as much as possible. For simplicity and convenient labelling, the shapes and thicknesses of the elements may be exaggerated in the drawings. It is easily understood: the elements belonging to the conventional technologies and well known by the persons skilled in the art may be not particularly depicted in the drawings or described in the specification. Various modifications and variations made by the persons skilled in the art according to the contents of the present invention are to be included by the scope of the present invention.

Refer to FIG. 1 and FIGS. 2A-2H for a first embodiment of a manufacturing method of an optical image sensor module according to the present invention. In the first embodiment, the manufacturing method of an optical image sensor module of the present invention comprises Steps S11-S16. It should be explained herein: the sequence and practical operations of the steps of the method are not limited by the description of the embodiment but may be adjusted according to requirement.

As shown in FIG. 1 and FIGS. 2A-2C, Step S11 includes providing a lens module array 10. In FIG. 2A, the lens module array 10 is formed by stacking a plurality of lens layers 11. The plurality of lens layers 11 includes at least three layers. In order to clarify the relative positions of the plurality of lens layers 11, the lens layers are respectively denoted by 111, 112, and 113. The lens layers 111, 112, and 113 are stacked in sequence. Each of the lens layers 111, 112, and 113 has a stack-alignment structure 11B. The stack-alignment structures 11B of the lens layers 111, 112, and 113 are press-fitted to each other. In FIG. 2B and FIG. 2C, the surface 110 of each of the lens layers 11 has a plurality of alignment marks 11A. The plurality of alignment marks 11A is arranged on the surface 110. The lens layers 11 cooperate with the plurality of alignment marks 11A to define a plurality of lens units 12 arranged in array. The lens layer 11 has a plurality of imaging areas 120A and a non-imaging area 120B. The plurality of imaging areas 120A is arranged in array. The non-imaging area 120B surrounds the plurality of imaging areas 120A. As shown in FIG. 2C, the edges of the lens layer 11 has a stack-alignment structure 11B. The stack-alignment structure 11B surrounds the edges of the bottom of the lens layer 11. The surface 110 of the lens layer 11 protrudes with respect to the stack-alignment structure 11B. The bottom of the lens layer 11 also has a fitting portion 11C. In stacking the lens layers 11, the surface of the lower lens layer 11 may be press-fitted into the fitting portion 11C of the upper lens layer 11. The lens layers 11 may be aligned to each other according to the stack-alignment structure 11B and then stacked.

In some embodiments, the lens module array 10 may be fabricated by using molds or an injection-molding technology. The lenses of different lens layers 11 may be arranged in array. The alignment marks 11A, the stack-alignment structures 11B or other similar marks may be fabricated on the edges of the array to facilitate stack alignment and cutting operation. The embodiments, which use molds or an injection-molding technology to fabricate different lens layers 11 of the lens module array 10 within the allowable tolerance, can reduce cost. For the alignment and assemblage of the wafer-level small-size array-type lens assembly, the lens module array 10 of the present invention may achieve a quality of the lenses, which is much better than the quality of the lenses formed by stacking the conventional wafer-level lenses. The lens module array 10 of the present invention has higher precision and resolution, applicable to the image sensors having more pixels.

Refer to FIG. 1 and FIGS. 2D-2G. Step S12 includes filling a adhesive material 13 into the gaps between the plurality of lens layers 11 and fix the lens layers 11 adhesively to form the plurality of lens units 12. During stacking, the upper and lower lens layers 11 may be filled with resin and fixed together adhesively using a fixture and the alignment marks 11A or the stack-alignment structure. For simplicity and conciseness, only a single lens unit 12 is used for illustration in FIGS. 2D-2G. However, these drawings are not to limit the present invention but only for exemplification. As mentioned above, the plurality of imaging areas 120A of the lens layer 11 is arranged in array, and the non-imaging area 120B surrounds the plurality of imaging areas 120A. In FIG. 2D and FIG. 2E, the adhesive material 13 is filled into the non-imaging areas 120B to form the lens unit 12. In FIG. 2F and FIG. 2G, the adhesive material 13 is filled into the imaging areas 120A and the non-imaging area 120B to form the lens unit 12′. It should be noted: the optical designs of endoscopes may be different in practical applications. Therefore, the adhesive materials used in this step may be different to meet different optical designs, including high optical transmission materials and light-shielding materials. Further, the adhesive materials, which are filled into the gaps between layers, may respectively have different refractive indexes, whereby the flexibility of optical design is enhanced.

As shown in FIG. 1 and FIG. 2H, Step S13 includes cutting the lens module array 10 along the plurality of alignment marks 11A to form a plurality of glue runners 15.

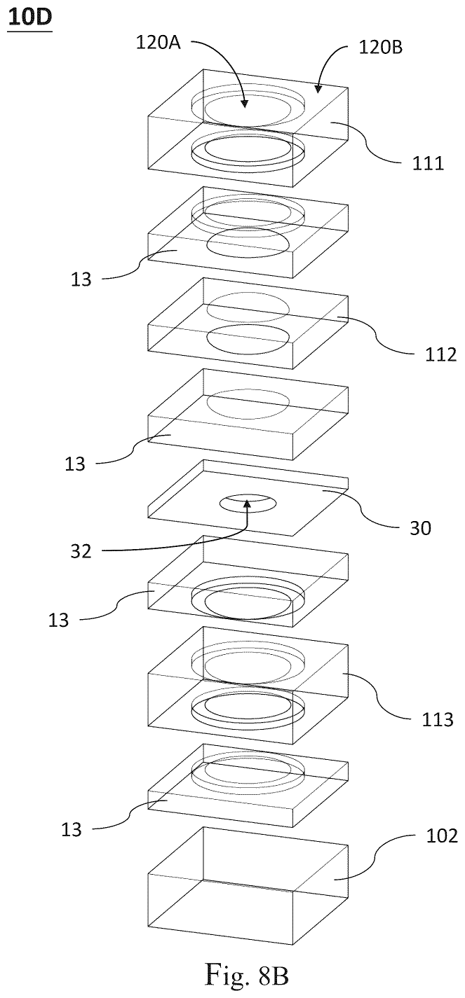

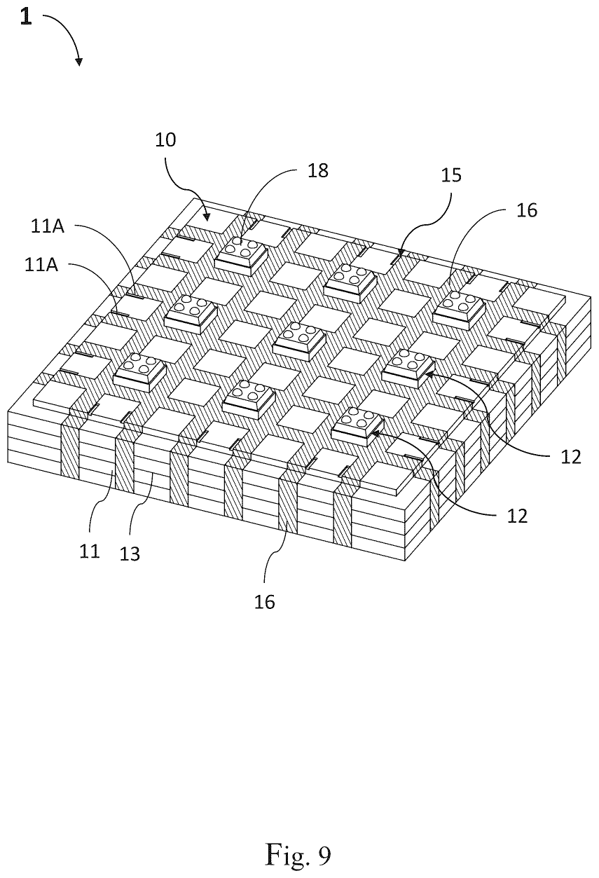

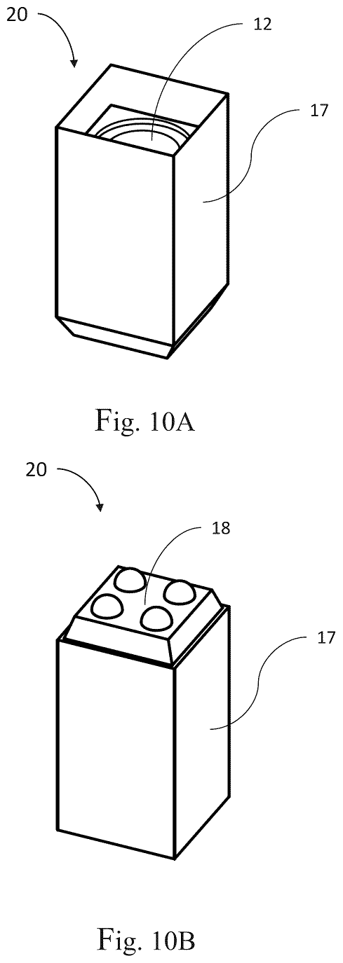

As shown in FIG. 1 and FIG. 21, Step S14 includes attaching one side of an image sensor 18 onto one surface of each lens unit 12/12′, wherein another side of the image sensor 18 protrudes outward with respect to the lens unit 12/12′ and neighbors the surface of the lens module array 10. Thus, this step attaches the image sensors 18 to the stack-type lens module array 10, whereby to achieve a wafer-level production mode and realize mass production.

As shown in FIG. 1 and FIG. 2J, Step S15 includes filling a light-shielding material 16 into the plurality of glue runners 15 and curing the light-shielding material 16 to make the light-shielding material 16 wrap the perimeters of the plurality of lens units 12/12′ to form an optical image sensor module array 1A, wherein the light-shielding material 16 is prevented from covering the surface of the lens units 12/12′.

It should be noted: wafer-level optical measurement steps may be added to the method according to requirement. For example, a wafer-level optical measurement may be performed after Step S15 to examine whether there are defective products in the lens units 12/12′; if there is a defective product, a mark is labeled to the position of the defective product; if there is no defective product, the process proceeds to perform Step S16. Through performing the wafer-level optical measurement and labeling the defective products, the succeeding steps may neglect the defective products and will not undertake related assemblage steps. Thereby, efficiency is increased, and waste is reduced. It should be noted: the lens module array 10 may be unsuitable to be measured while the sidewalls thereof are free of the light-shielding material 16. Therefore, the optical measurements of the lens module array 10 would not be performed unless the light-shielding material 16 has been filled into the glue runners 15 of the lens module array 10 and cured.

As shown in FIG. 1 and FIG. 2K, Step S16 includes cutting the light-

shielding material 16 along the sidewalls of the glue runners 16 to separate the plurality of lens units 12/12′, wherein optical-blocking layers 17 are formed around the perimeters of the plurality of the lens units 12/12′, whereby to generate a plurality of optical image sensor modules 20. During cutting the light-shielding material 16, an appropriate cutting method may be used to make the surface of the lens unit 12/12′ smaller than or equal to the size of the image sensor 18. The abovementioned cutting method may be an oblique cutting method or using a dicing-saw having a smaller thickness. Thus, a preset thickness of the light-shielding material 16 may be reserved to form the optical-blocking layer 17 lest stray light enter the lens unit 12/12′ and affect the imaging quality.

After cutting, the optical image sensor module array 1A is diced into a plurality of optical image sensor modules 20. The method of the present invention can mass produce a great number of wafer-level optical image sensor modules 20 of endoscopic lens assemblies. In Step S16, a preset thickness of the light-shielding material 16 is reserved to function as the optical-blocking layer 17 of the lenses lest stray light enter the lens unit 12/12′ and affect the imaging quality. The optical-blocking material is hard to fabricate on a single lens. The present invention overcomes the aforementioned problem via generating the lens units 12/12′ in form of array, using the glue runners 15 to receive the light-shielding material, and cutting the filled light-shielding material along the glue runners to form the optical-blocking layers. Therefore, the present invention can increase efficiency and yield. Further, the present invention can directly integrate the lenses with the image sensor 18 to form the optical image sensor module 20 having the function of capturing images.

In FIGS. 2A-2K, the surface 110 of the lens layer 11 is faced upward so as to favor fabrication and assemblage in this embodiment. While the finished optical image sensor module 20 is practically applied to an endoscope, the optical image sensor module 20 is flipped over to make the image sensor 18 positioned on the bottom of the overall optical image sensor module 20; then, the optical image sensor module 20 is electrically connected to other elements. The right portion of FIG. 2K shows that the optical image sensor module 20, which is obtained via cutting the optical image sensor module array 1A, is flipped over 180 degrees. However, the present invention is not limited by the drawing. The optical image sensor module 20 may be turned by appropriate degrees according to practical requirement.

Refer to FIG. 3, FIG. 4A and FIG. 4B for a second embodiment of a manufacturing method of an optical image sensor module according to the present invention. In the second embodiment, the manufacturing method of an optical image sensor module of the present invention comprises Steps S21-S26. The second embodiment is different from the first embodiment in Step S24 and Step S25. Besides, Step S21 is the same as Step S11; Step S22 is the same as Step S12; Step S23 is the same as Step S13; Step S26 is the same as Step S16. The identical steps will not repeat herein.

Refer to FIG. 3 and FIG. 4A. Step S24 includes filling the light-shielding material 16 into the plurality of glue runners 15 and curing the light-shielding material 16 to make the light-shielding material 16 wrap the perimeters of the plurality of lens units 12, wherein the light-shielding material 16 is prevented from covering the surfaces of the plurality of lens units 12.

Refer to FIG. 3 and FIG. 4B. Step S25 includes attaching one side of an image sensor 18 onto one surface of each lens unit 12, wherein another side of the image sensor 18 protrudes outward with respect to the lens unit 12 and neighbors the surface of the lens module array 10, whereby to form the optical image sensor module array 1B.

In Step S25 of this embodiment, the image sensors 18 are attached onto the lens units 12 where the first cutting operation has been undertaken and the light-shielding material 16 has been filled into the glue runners 15. After Step S25, wafer-level optical measurements may be performed to inspect whether there are defective products in the lens units 12, whereby to verify the imaging quality of the lens units 12 and save the time spent on measuring individual lens units 12 in the following operation. If there is a defective product, a mark is labeled to the position of the defective product; if there is no defective product, the process proceeds to perform Step S26 and undertake the second cutting operation. After the second cutting operation, a plurality of image sensor modules is generated.

Refer to FIG. 5 and FIGS. 6A-6C for a third embodiment of a manufacturing method of an optical image sensor module according to the present invention. In the third embodiment, the manufacturing method of an optical image sensor module of the present invention comprises Steps S31-S36. The third embodiment is different from the first embodiment in Steps S32-35. Besides, Step S31 is the same as Step S11; Step S36 is the same as Step S16. The identical steps will not repeat herein.

Refer to FIG. 5 and FIG. 6A. Step S32 includes attaching one side of an image sensor 18 onto one surface of each lens unit 12, wherein another side of the image sensor 18 protrudes outward with respect to the lens unit 12 and neighbors the surface of the lens module array 10.

Step S33 is the same as Step S12, which has been shown in FIGS. 2D-2G. Step S33 includes filling a adhesive material 13 into the gaps between the plurality of lens layers 11 and fix the lens layers 11 adhesively.

Refer to FIG. 5 and FIG. 6B. Step S34 includes cutting the lens module array 10 along the plurality of alignment marks 11A to form a plurality of glue runners 15.

Refer to FIG. 5 and FIG. 6C. Step S35 includes filling the light-shielding material 16 into the plurality of glue runners 15 and curing the light-shielding material 16 to make the light-shielding material 16 wrap the perimeters of the plurality of lens units 12, wherein the light-shielding material 16 is prevented from covering the surfaces of the plurality of lens units 12, whereby to form an optical image sensor module array 1C.

In the abovementioned steps of the present invention, the image sensors 18 may be screened to find out normal ones. Then, the normal image sensors 18 (known Good Dies (KGD)) are assembled to the lens units 12. Thus, the present invention can overcome the problem: the conventional wafer-level package technology cannot screen the image sensors but must assemble all the image sensors simultaneously. Therefore, the present invention can promote the yield of assembling image sensors.

Refer to FIG. 7A, FIG. 7B, FIG. 8A and FIG. 8B. Below are described other embodiments of the lens module array.

As shown in FIG. 7A, the lens module array 10A comprises a first flat lens 102 and a plurality of lens layers 11. The plurality of lens layers 11 includes a lens layer 111, a lens layer 112 and a lens layer 113. The lens layer 111, the lens layer 112, the lens layer 113 and the first flat lens 102 are arranged in sequence. The first flat lens 102 is arranged under the lens layer 113 and functions to protect the plurality of lens units 12. Based on FIG. 7A, the lens module array 10B comprises a first flat lens 102, a second flat lens 104, and a plurality of lens layers 11, as shown in FIG. 7B. The second flat lens 104 is arranged above the lens layer 111 and functions to adjust the back focus.

Refer to FIG. 8A and FIG. 8B where a single lens unit is used to represent a lens module array 10C for conciseness. The lens module array 10C comprises a shielding member 30 and a plurality of lens layers 11. The plurality of lens layers 11 includes a lens layer 111, a lens layer 112 and a lens layer 113. The shielding member 30 is interposed between the lens layer 112 and the lens layer 113. The shielding member 30 is a plate-like structure. The center of the shielding member 30 is perforated to have a through-hole 32. The through-hole 32 functions as a clear aperture. The diameter of the clear aperture is not limited by the drawing but may be adjusted according to requirement. FIG. 8A is corresponding to FIG. 7A but different from FIG. 7A in that an adhesive material 13 is filled into the non-imaging area 120B after the shielding member 30 has been interposed between the lens layer 112 and the lens layer 113. FIG. 8B is different from FIG. 7A in that an adhesive material 13 is filled into the imaging areas 120A and the non-imaging area 120B after the shielding member 30 has been interposed between the lens layer 112 and the lens layer 113. In FIG. 8A and FIG. 8B, the shielding member 30, which is a physical object, functions as an aperture to prevent the light outside the through-hole 32 from entering the lenses and the sensor and promote the imaging quality.

The optical image sensor module array and the optical image sensor module, which are fabricated by the manufacturing method of an optical image sensor module of the present invention, have been also introduced in the description of the method. However, the optical image sensor module array and the optical image sensor module will be further demonstrated in details below with the schematic illustrations to make the readers understand them more clearly.

Refer to FIG. 9. An optical image sensor module array 1 may be manufactured according to the embodiments of the aforementioned manufacturing method of an optical image sensor module. Refer to FIGS. 2A-2K to understand the details of the optical image sensor module array 1. The optical image sensor module array 1 comprises a lens module array 10, an optical-blocking layer 17, and image sensors 18. The lens module array 10 includes a plurality of lens layers 11 and a plurality of alignment marks 11A. The plurality of lens layers 11 is stacked up. A adhesive material 13 is filled into the gaps between the plurality of lens layers 11 to fix the lens layers 11 adhesively. A plurality of alignment marks 11A is arranged on the surfaces of the plurality of lens layers 11. The plurality of lens layers 11 cooperates with the plurality of alignment marks 11A to define a plurality of lens units 12, which are arranged in array. A plurality of glue runners 15 is formed on the plurality of lens layers 11 along the plurality of alignment marks 11A by dicing processes. An optical-blocking layer 17 is disposed inside the plurality of glue runners 15, wrapping the outer sidewalls of the lens units 12 and prevented from covering the surfaces of the lens units 12. One side of each of the plurality of image sensors 18 is attached onto one surface of each of the plurality of lens units 12; another side of each of the plurality of image sensors 18 protrudes outward and is adjacent to the surface of the lens units 12.

Although no stack-alignment structure 11B is depicted on the edges of the plurality of lens layers 11 in FIG. 9, it can be learned from FIG. 2B and FIG. 2C: each lens layer 11 is aligned to the adjacent lens layer 11 and stacked above the adjacent lens layer 11 according to the stack-alignment structures 11B. The stack-alignment structures 11B of the lens layers 11 surround the perimeters of the bottoms of the lens layers 11, and the lens layers 11 protrude from the stack-alignment structures 11B, whereby the stack-alignment structures 11B may fitting to each other to complete the stacking of the plurality lens layers 11. It should be noted: the shape, and size of the stack-alignment structures 11B is not limited by the attached drawings but may be varied according to requirement.

It is preferred: the image sensor 18 is a CSP (Chip Scale Package) image sensor. The image sensor chip is packaged on the package substrate having the same size as the image sensor chip, whereby to reduce the size and weight of the package as much as possible. The image sensor 18 may be but is not limited to be an RGB image sensor, an infrared image sensor, a monochromatic image sensor, or a specialty image sensor.

Refer to FIG. 10A and FIG. 10B, wherein FIG. 10A is the image of an optical image sensor module 20 and FIG. 10B is the image of the optical image sensor module 20 flipped over 180 degrees. The optical image sensor module 20 is obtained via cutting the optical image sensor module array 1. The optical image sensor module 20 comprises a lens unit 12, an optical-blocking layer 17, and an image sensor 18.

Refer to FIGS. 2A-2H. The lens unit 12 includes a plurality of lens layers 11 and a adhesive material 13. The plurality of lens layers 11 is stacked up. The adhesive material 13 is disposed between the lens layers 11 to fix the lens layers 11 adhesively. The optical-blocking 17 wraps the outer sidewalls of the lens unit 12 and is prevented from covering the surface of the lens unit 12. One side of the image sensor 18 is attached onto one surface of the lens unit 12; another side of the image sensor 18 protrudes outward with respect to the lens unit 12 and neighbors the surface of the lens unit 12.

Below are stated the efficacies of the optical image sensor module array, the optical image sensor module, and the manufacturing method of the present invention: the present invention needn't coat the light-shielding layer individually but simulates the mass-production mode of wafer-level package via integrating the image sensors and the lens module array to reduce fabrication time, raise efficiency and promote yield; the present invention can be fabricated in a cost much lower in cost than conventional wafer-level lenses and has higher yield, wherefore the present invention can reduce cost; the present invention adopts the products, which have been verified optically and function normally, before or during assemblage, wherefore the present invention can guarantee the yield of mass-assemblage of integral modules; the present invention shields stray light to promote the image quality of the image sensors; the present invention can produce a miniaturized optical image sensor module with lenses, which may be used to detect micro images.

The embodiments described above are only to exemplify the present invention but not to limit the scope of the present invention. The embodiments involving equivalent replacement or variation made easily according to the technical contents disclosed by the specification or claims are to be also included by the scope of the present invention.

While the invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the appended claims.

1. A manufacturing method of an optical image sensor module, which comprises steps of:
providing a lens module array, wherein the lens module array is formed by stacking a plurality of lens layers; the plurality of lens layers respectively has a surface and a plurality of alignment marks; the plurality of alignment marks is disposed on the surface; the plurality of lens layers and the plurality of alignment marks define a plurality of lens units arranged in array;
filling an adhesive material into gaps between the plurality of lens layers to fix the plurality of lens layers adhesively and form the plurality of lens units;
cutting the lens module array along the plurality of alignment marks to form a plurality of glue runners;
filling a light-shielding material into the plurality of glue runners and curing the light-shielding material to make the light-shielding material wrap perimeters of the plurality of lens units, wherein the light-shielding material is prevented from covering the surface of the plurality of lens units;
wherein one side of an image sensor is attached onto one surface of each lens unit before filling the light-shielding material into the plurality of glue runners and curing the light-shielding material or after filling the light-shielding material into the plurality of glue runners and curing the light-shielding material or before the adhesive material is filled into the gaps between the plurality of lens layers; another side of the image sensor protrudes outward with respect to the lens unit and is adjacent to the surface of the lens module array to form an optical image sensor module array; and
cutting the light-shielding material along sidewalls of the plurality of glue runners to separate the plurality of lens units and form optical-blocking layers around perimeters of the plurality of lens units to generate a plurality of optical image

2. The manufacturing method of an optical image sensor module according to claim 1, wherein in the step of providing the lens module array, stack-alignment structures are respectively formed on edges of the plurality of lens layers; the plurality of lens layers are aligned and stacked up according to the stack-alignment structures.

3. The manufacturing method of an optical image sensor module according to claim 2, wherein in the step of aligning and stacking up the plurality of lens layers according to the stack-alignment structures, the stack-alignment structure surrounds edges of a bottom of the lens layer; the lens layer protrudes from the stack-alignment structure; the stack-alignment structures are press-fitted to each other to enable stacking up of the plurality of lens layers.

4. The manufacturing method of an optical image sensor module according to claim 1, wherein after the step of attaching one side of an image sensor onto one surface of each lens unit, the manufacturing method further comprises a step of:
performing a wafer-level optical measurement to examine whether there are defective products in the lens units; if there is a defective product, a mark is labeled to a position of the defective product; if there is no defective product, the process proceeds to the step of cutting the light-shielding material along the sidewalls of the plurality of glue runners.

5. The manufacturing method of an optical image sensor module according to claim 1, wherein after the step of filling the light-shielding material into the plurality of glue runners and curing the light-shielding material to make the light-shielding material wrap the perimeters of the plurality of lens units with the light-shielding material prevented from covering the surface of the plurality of lens units, the manufacturing method further comprises a step of:
performing a wafer-level optical measurement to examine whether there are defective products in the lens units; if there is a defective product, a mark is labeled to a position of the defective product; if there is no defective product, the process proceeds to the step of cutting the light-shielding material along the sidewalls of the plurality of glue runners.

6. The manufacturing method of an optical image sensor module according to claim 1, wherein the plurality of lens layers respectively has a plurality of imaging areas and a non-imaging area; the plurality of imaging areas arranged in array; the non-imaging area surrounds the plurality of imaging areas; in the step of filling the adhesive material into the gaps between the plurality of lens layers to fix the plurality of lens layers adhesively, the adhesive material is filled into the non-imaging area or into the non-imaging area and the imaging areas.

7. The manufacturing method of an optical image sensor module according to claim 1, wherein the plurality of lens layers includes a first flat lens; the first flat lens is arranged under the plurality of lens layers to function as a protective layer of the plurality of lens units.

8. The manufacturing method of an optical image sensor module according to claim 1, wherein the plurality of lens layers includes a second flat lens; the second flat lens is arranged above the plurality of lens layers and functions to adjust back focus of the overall lens units.

9. The manufacturing method of an optical image sensor module according to claim 1, wherein the step of cutting the light-shielding material along the sidewalls of the plurality of glue runners to separate the plurality of lens units, an area of a surface of the lens unit is smaller than or equal to a size of the image sensor.

10. An optical image sensor module array, comprising:
a lens module array, including a plurality of lens layers and a plurality of alignment marks, wherein the plurality of lens layers is stacked up; an adhesive material is disposed between the plurality of lens layers; the plurality of alignment marks is arranged on surfaces of the plurality of lens layers; the plurality of lens layers and the plurality of alignment marks define a plurality of lens units arranged in array; a plurality of glue runners is formed in the plurality of lens layers along the plurality of alignment marks;
an optical-blocking layer, disposed inside the plurality of glue runners, wrapping outer sidewalls of the lens units, and prevented from covering surfaces of the lens units; and
a plurality of image sensors, wherein one side of the image sensor is attached onto one surface of the lens unit; another side of the image sensor protrudes outward with respect to the lens unit and neighbors one surface of the lens module array.

11. The optical image sensor module array according to claim 10, wherein stack-alignment structures are respectively formed on edges of the plurality of lens layers; two adjacent lens layers of the plurality of lens layers are aligned to each other and stacked up according to the stack-alignment structures.

12. The optical image sensor module array according to claim 11, wherein each of the stack-alignment structures surrounds the edges of a bottom of a corresponding one of the plurality of lens layers; the lens layer protrudes from the corresponding stack-alignment structure; the stack-alignment structures are press-fitted to each other while the plurality of lens layers is stacked up.

13. The optical image sensor module array according to claim 10, wherein each of the plurality of lens layers has a plurality of imaging areas and a non-imaging area; the plurality of imaging areas is arranged in array; the non-imaging area surrounds the plurality of imaging areas; the adhesive material is disposed on the non-imaging area or disposed on the non-imaging area and the plurality of imaging areas.

14. The optical image sensor module array according to claim 10, wherein the plurality of lens layers includes a first flat lens; the first flat lens is disposed on a bottom of the plurality of lens layers and functions as a protective layer of the plurality of lens layers.

15. The optical image sensor module array according to claim 10, wherein the plurality of lens layers includes a second flat lens; the second flat lens is disposed on a top of the plurality of lens layers and functions to adjust back focus of the plurality of lens units.

16. The optical image sensor module array according to claim 10, wherein a surface of each of the plurality of lens units is smaller than or equal to a size of each image sensor.

17. An optical image sensor module array, comprising:
a lens module array, including a plurality of lens layers, a plurality of alignment marks and a shielding member, wherein the plurality of lens layers is stacked up; an adhesive material is disposed between the plurality of lens layers; the plurality of alignment marks is arranged on surfaces of the plurality of lens layers; the plurality of lens layers and the plurality of alignment marks define a plurality of lens units arranged in array; a plurality of glue runners is formed in the plurality of lens layers along the plurality of alignment marks; the shielding member is located between two of the plurality of lens layers, and the shielding member has a sheet-like structure with a central hollow portion that forms a through-hole, and the through-hole functions as a clear aperture;
an optical-blocking layer, disposed inside the plurality of glue runners, wrapping outer sidewalls of the lens units, and prevented from covering surfaces of the lens units; and
a plurality of image sensors, wherein one side of the image sensor is attached onto one surface of the lens unit; another side of the image sensor protrudes outward with respect to the lens unit and neighbors one surface of the lens module array.

18. The optical image sensor module array according to claim 17, wherein each of the plurality of lens layers has a plurality of imaging areas and a non-imaging area; the plurality of imaging areas is arranged in array; the non-imaging area surrounds the plurality of imaging areas; the adhesive material is disposed on the non-imaging area or disposed on the non-imaging area and the plurality of imaging areas.

19. The optical image sensor module array according to claim 17, wherein the plurality of lens layers includes a first flat lens; the first flat lens is disposed on a bottom of the plurality of lens layers and functions as a protective layer of the plurality of lens layers.

20. An optical image sensor module, which is manufactured by the manufacturing method of an optical image sensor module according to claim 1.
